(19) United States
(12) Patent Application Publication
(10) Pub. No.: US 2025/0361440 A1
(43) Pub. Date: Nov. 27, 2025

(54) ETCHING METHOD

(71) Applicant: Resonac Corporation, Tokyo (JP)

(72) Inventors: Kazuma MATSUI, Tokyo (JP); Yuki OKA, Tokyo (JP); Moe TANIWAKI, Tokyo (JP)

(73) Assignee: Resonac Corporation, Tokyo (JP)

(21) Appl. No.: 18/867,945

(22) PCT Filed: May 30, 2023
(86) PCT No.: PCT/JP2023/020125

§ 371 Date: Nov. 21, 2024

(30) Foreign Application Priority Data
May 31, 2022 (JP) 2022-089057

(51) Int. Cl. C09K 13/00; H01L 21/311

(52) U.S. Cl. CPC C09K 13/00; H01L 21/31116; H01L 21/31144

(57) ABSTRACT

An etching method includes an etching step of bringing an etching gas containing an etching compound into contact with a member to be etched (400) having an etching object (silicon material) and a non-etching object (carbon material) and selectively etching the etching object over the non-etching object. The etching compound is fluoro-dithiethane represented by Chemical Formula CₓF_{y}S₂, wherein, in Chemical Formula, x is 2 or more and 6 or less and y is 4 or more and 12 or less. The etching gas contains or does not contain at least one type of metal among sodium, magnesium, aluminum, potassium, calcium, chromium, manganese, iron, cobalt, nickel, copper, and molybdenum, and, when the at least one type of metal is contained, the total concentration of all types of the contained metals is 300 ppb by mass or less.

### TECHNICAL FIELD

The present invention relates to an etching method.

### BACKGROUND ART

The most advanced dry etching process has been required to have excellent etching characteristics, such as an etching selectivity, an etching rate, and vertical processability. The development of a novel etching gas satisfying the requirements has been desired.

PTLS 1, 2 disclose dry etching methods for etching silicon materials, such as silicon oxide and silicon nitride, with a carbon material, such as amorphous carbon, as a mask using an etching gas containing a sulfur-containing compound as an etching compound.

### CITATION LIST

### Patent Literatures

PTL 1: WO 2020/085468
PTL 2: JP 2020-155773 A

### SUMMARY OF INVENTION

### Technical Problem

With the miniaturization of semiconductor devices and the development of three-dimensional semiconductor devices, the dry etching process has been required to be further improved in the etching characteristics described above, particularly an etching selectivity, which is a ratio of the etching rate of the silicon material to the etching rate of the carbon material.

It is an object of the present invention to provide an etching method having a high etching selectivity, which is the ratio of the etching rate of the silicon material to the etching rate of the carbon material.

### Solution to Problem

To achieve the above-described object, one aspect of the present invention is as described in [1] to [7] below.
[1] An etching method includes: an etching step of bringing an etching gas containing an etching compound into contact with a member to be etched having an etching object subject to etching by the etching gas and a non-etching object not subject to etching by the etching gas and selectively etching the etching object over the non-etching object, in which
the etching object has a silicon material and the non-etching object has a carbon material,
the etching compound is fluoro-dithiethane represented by Chemical Formula CₓF_{y}S₂, wherein, in Chemical Formula above, x is 2 or more and 6 or less and y is 4 or more and 12 or less, and
the etching gas contains or does not contain at least one type of metal among sodium, magnesium, aluminum, potassium, calcium, chromium, manganese, iron, cobalt, nickel, copper, and molybdenum, and, when the at least one type of metal is contained, the total concentration of all types of the contained metals is 300 ppb by mass or less.
[2] The etching method according to [1], in which the fluoro-dithiethane has at least one type among 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane.
[3] The etching method according to [1] or [2], in which the silicon material has at least one of a silicon compound and polysilicon, and the silicon compound is a compound having at least one of an oxygen atom and a nitrogen atom, and a silicon atom.
[4] The etching method according to any one of [1] to [3], in which the carbon material has at least one of a photoresist and amorphous carbon.
[5] The etching method according to any one of [1] to [4], in which the etching gas contains the fluoro-dithiethane and at least one of a second etching compound and an inert gas.
[6] The etching method according to [5], in which the second etching compound is at least one type among nitrogen trifluoride, sulfur hexafluoride, chlorine gas, hydrogen gas, and fluorocarbon having 1 or more and 7 or less carbon atoms.
[7] The etching method according to [6], in which the fluorocarbon is at least one type among tetrafluoromethane, difluoromethane, and hexafluorobutadiene.

### Advantageous Effects of Invention

According to the present invention, the etching selectivity, which is the ratio of the etching rate of the silicon material to the etching rate of the carbon material, is high.

### BRIEF DESCRIPTION OF DRAWINGS

FIG. 1 is a schematic view illustrating one example of an etching device for explaining one embodiment of an etching method according to the present invention;

FIG. 2 is a schematic view illustrating one example of a purification device purifying fluoro-dithiethane or sulfur hexafluoride;

FIG. 3 is a schematic view illustrating one example of a preparation device preparing an aqueous nitric acid solution to be used for the measurement of the concentration of metal in fluoro-dithiethane; and

FIG. 4 is a schematic view illustrating one example of a preparation device preparing an aqueous nitric acid solution to be used for the measurement of the concentration of metal in the sulfur hexafluoride.

### DESCRIPTION OF EMBODIMENTS

Hereinafter, one embodiment of the present invention is described. This embodiment describes one example of the present invention, and the present invention is not limited to this embodiment. This embodiment can be variously altered or improved, and such altered or improved aspects can also be included in the present invention.

An etching method according to this embodiment includes an etching step of bringing an etching gas containing an etching compound into contact with a member to be etched having an etching object subject to etching by the etching gas and a non-etching object not subject to etching by the etching gas and selectively etching the etching object over the non-etching object.

The etching object has a silicon material and the non-etching object has a carbon material. The etching compound is fluoro-dithiethane represented by Chemical Formula CₓF_{y}S₂. In Chemical Formula above, x is 2 or more and 6 or less and y is 4 or more and 12 or less.

The etching gas contains or does not contain at least one type of metal among sodium (Na), magnesium (Mg), aluminum (Al), potassium (K), calcium (Ca), chromium (Cr), manganese (Mn), iron (Fe), cobalt (Co), nickel (Ni), copper (Cu), and molybdenum (Mo), and, when the at least one type of metal is contained, the total concentration of all types of the contained metals is 300 ppb by mass or less.

When the etching gas containing an etching compound is brought into contact with the member to be etched, the silicon material, which is the etching object, and the etching compound in the etching gas react with each other, and therefore the etching of the silicon material progresses. In contrast thereto, the carbon material, which is the non-etching object, hardly reacts with the etching compound, and therefore the etching of the carbon material hardly progresses. Thus, according to the etching method of this embodiment, the silicon material can be selectively etched over the carbon material (i.e., high etching selectivity is obtained).

Further, according to the etching method of this embodiment, the etching is performed using the etching gas not containing the metals or containing the metals in an extremely small amount, even when the etching gas contains the metals as descried above, and therefore the etching selectivity, which is a ratio of the etching rate of the silicon material to the etching rate of the carbon material, is high.

Therefore, according to the etching method of this embodiment, the etching selectivity, which is the ratio of the etching rate of the silicon material to the etching rate of the carbon material, can be set to 1.2 or more, for example. The etching selectivity is preferably 2 or more and more preferably 30 or more.

Thus, the etching method according to this embodiment can be utilized for the manufacture of semiconductor elements. For example, when the etching method according to this embodiment is applied to a semiconductor substrate having a thin film containing a silicon material and a thin film containing a carbon material, and the thin film containing a silicon material is etched with the thin film containing a carbon material as a mask, a three-dimensionally integrated semiconductor element can be manufactured.

The etching in the present invention means removing entirely or partially the etching object possessed by the member to be etched to process the member to be etched into a predetermined shape (e.g., three-dimensional shape) (e.g., processing a film-like etching object containing a silicon material possessed by the member to be etched to have a predetermined film thickness). The “metal” in the “metal concentration” in the present invention includes metal atoms and metal ions.

Hereinafter, the etching method according to this embodiment is described in more detail.

### [Etching Method]

For the etching method according to this embodiment, both plasma etching using plasma or plasmaless etching not using plasma are usable. The plasma etching includes reactive ion etching (RIE), inductively coupled plasma (ICP) etching, capacitively coupled plasma (CCP) etching, electron cyclotron resonance (ECR) plasma etching, and microwave plasma etching, for example.

In the plasma etching, plasma may be generated in a chamber where the member to be etched is placed or a plasma generating chamber and the chamber where the member to be etched is placed may be separated from each other (i.e., remote plasma may be used). By etching using the remote plasma, the silicon material, which is the etching object, can be sometimes etched with higher selectivity.

### [Etching Compound]

The etching compound contained in the etching gas is a compound that hardly reacts with the carbon material but reacts with the silicon material and advances the etching of the silicon material. The etching compound is the fluoro-dithiethane represented by Chemical Formula CₓF_{y}S₂, wherein, in Chemical Formula above, x is 2 or more and 6 or less and y is 4 or more and 12 or less. However, from the viewpoint of ease of accessibility and ease of handling, fluoro-dithiethane, wherein, in Chemical Formula above, x is 2 or more and 4 or less and y is 4 or more and 12 or less, is preferable. The etching compounds may be used alone or in combination of two or more types thereof.

The fluoro-dithiethane represented by Chemical Formula CₓF_{y}S₂ includes fluoro-dithiethane having a 1,2-dithietane structure and fluoro-dithiethane having a 1,3-dithietane structure, both of which are usable as the etching compound in the etching method according to this embodiment. From the viewpoint of ease of accessibility, the fluoro-dithiethane having a 1,3-dithietane structure is preferable and fluoro-dithiethane having a 1,3-dithietane structure and having no unsaturated bonds is more preferable.

When the etching is performed using an etching gas containing the above-described fluoro-dithiethane, a film of a compound having a carbon-sulfur bond is formed on the surface of the carbon material. The compound film has relatively high resistance to activated species that are generated from combinations of chemical species, such as a fluorine atom, a chlorine atom, a bromine atom, an oxygen atom, a carbon atom, and a nitrogen atom, and that are effective for the etching of the silicon material. Therefore, this compound film has an action of suppressing the etching of the carbon material. As a result, the silicon material is selectively etched over the carbon material.

Examples of the fluoro-dithiethane having a 1,3-dithietane structure and having no unsaturated bonds include 2,2,4,4-tetrafluoro-1,3-dithietane (C₂F₄S₂, see Chem. 1), 1,1,2,2,3,3,4,4-octafluoro-1,3-dithietane (C₂F₈S₂, see Chem. 2), 1,1,2,2,4,4-hexafluoro-1,3-dithietane (C₂F₆S₂, see Chem. 3), 1,1,1,1,2,2,3,3,3,3,4,4-dodecafluoro-1,3-dithietane (C₂F₁₂S₂, see Chem. 4), 2,2,4-trifluoro-4-trifluoromethyl-1,3-dithietane (C₃F₆S₂, see Chem. 5), 2,4-difluoro-2,4-bis(trifluoromethyl)-1,3-dithietane (C₄F₈S₂, see Chem. 6), and 2,2,4,4-tetrakis(trifluoromethyl)-1,3-dithietane (C₆F₁₂S₂, see Chem. 7).

Among the fluoro-dithiethanes above, the fluoro-dithiethanes are more preferably 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane, and 2,2,4,4-tetrafluoro-1,3-dithietane is still more preferable due to relatively ease of vaporization.

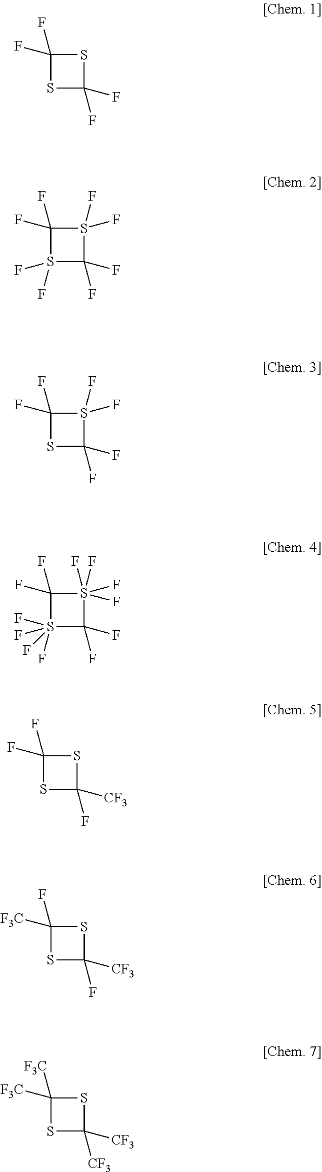

### [Etching Gas]

The etching gas is a gas containing the etching compound (fluoro-dithiethane), and may be a gas containing only the etching compound or may be a mixed gas containing the etching compound and the other type of gas other than the etching compound.

When the etching gas is the mixed gas containing the etching compound and the other type of gas, the concentration of the etching compound contained in the etching gas is not particularly limited insofar as it is the concentration at which the silicon material can be processed. The concentration of the etching compound contained in the etching gas can be set to more than 0% by volume and less than 100% by volume, for example, and is preferably 1% by volume or more and 50% by volume or less, more preferably 3% by volume or more and 30% by volume or less, still more preferably 5% by volume or more and 20% by volume or less, and particularly preferably 10% by volume or more and 20% by volume or less.

When the concentration of the etching compound in the etching gas is in the numerical ranges above, the etching rate of the silicon material is likely to increase. Further, the plasma etching resistance of the carbon material increases, and therefore the etching selectivity of the silicon material to the carbon material is likely to increase.

The other type of gas other than the etching compound contained in the etching gas includes a second etching compound and an inert gas, for example. The etching gas may contain either one or both of the second etching compound and the inert gas.

A method for mixing the components in the etching gas includes a method for introducing the other type of gas other than the etching compound in an optional proportion into a container where the etching compound is stored or a method for supplying the etching compound and the other type of gas other than the etching compound to a container or an etching device while the flow rate of the etching compound and the flow rate of the other type of gas are being individually controlled, for example.

The second etching compound is a compound capable of etching at least a part of the member to be etched and is a compound other than the fluoro-dithiethane. Examples of the second etching compound include halogen-containing compounds, oxygen-containing compounds, and hydrogen gases (H₂). The halogen-containing compound is a compound having a halogen atom, such as a fluorine atom, a chlorine atom, a bromine atom, and an iodine atom, in the molecule. The oxygen-containing compound is a compound having an oxygen atom in the molecule. The second etching compounds may be used alone or in combination of two or more types thereof. The second etching compounds do not include compounds exemplified as impurities later.

When the etching gas contains the second etching compound together with the etching compound, the etching characteristics can be sometimes improved. Examples of the improved etching characteristics include improved accuracy of vertical processability, an improved etching rate of the silicon material, an improved etching selectivity, improved uniformity of an etching rate distribution in a wafer plane, and the like.

In this viewpoint, the hydrogen gases are particularly preferably used as the second etching compound. The concentration of the hydrogen gas in the etching gas can be set to 0% by volume or more and 30% by volume or less, for example, and is preferably set to more than 0% by volume and 20% by volume or less and more preferably set to 3% by volume or more and 10% by volume or less.

For example, when the etching gas contains the halogen-containing compound as the second etching compound together with the fluoro-dithiethane, the etching selectivity, which is the ratio of the etching rate of the silicon material to the etching rate of the carbon material, is sometimes improved by a factor of 1.2 or more as compared with a case where the etching gas does not contain the fluoro-dithiethane but contains the halogen-containing compound. When preferable conditions are satisfied, the etching selectivity is sometimes improved by a factor of 1.5 or more. When more preferable conditions are satisfied, the etching selectivity is sometimes improved by a factor of 2 or more.

Examples of the halogen-containing compound include fluorine gas (F₂), methyl chloride (CH₃Cl), dichloromethane (CH₂Cl₂), chloroform (CHCl₃), carbon tetrachloride (CCl₄), chlorine gas (Cl₂), boron trichloride (BCl₃), bromine (Br₂), hydrogen bromide (HBr), iodine (I₂), hydrogen iodide (HI), oxygen bifluoride (OF₂), chlorine trifluoride (ClF₃), bromine trifluoride (BrF₃), bromine pentafluoride (BrF₅), iodine pentafluoride (IF₅), iodine heptafluoride (IF₇), nitrogen trifluoride (NF₃), sulfur hexafluoride (SF₆), nitrosyl fluoride (NOF), and fluorocarbon.

The fluorocarbon is a compound in which some or all of the hydrogen atoms possessed by the hydrocarbon are replaced by fluorine atoms. Among the fluorocarbons, those having 1 or more and 7 or less carbon atoms are preferable, those having 1 or more and 5 or less carbon atoms are more preferable, and those having 1 or more and 4 or less carbon atoms are still more preferable from the viewpoint of ease of accessibility. The fluorocarbons may have atoms other than the carbon atoms and the fluorine atoms, and may have atoms, such as a hydrogen atom (H), a nitrogen atom (N), an oxygen atom (O), a sulfur atom(S), a chlorine atom (Cl), a bromine atom (Br), and an iodine atom (I), for example.

Specific examples of the fluorocarbon include tetrafluoromethane (CF₄), trifluoromethane (CHF₃), difluoromethane (CH₂F₂), fluoromethane (CH₃F), dibromodifluoromethane (CBr₂F₂), trifluoroiodomethane (CF₃I), carbonyl fluoride (COF₂), hexafluoroethane (C₂F₆), chlorotrifluoroethylene (C₂F₃Cl), 1-chloro-1-fluoroethylene (C₂H₂FCl), bromotrifluoroethylene (C₂F₃Br), 1-bromo-1-fluoroethylene (C₂H₂FBr), octafluoropropane (C₃F₈), octafluorocyclobutane (c-C₄F₈), hexafluorobutadiene (e.g., hexafluoro-1,3-butadiene (C₄F₆)), 1,1,1,3,3,3-hexafluoro-2-butene (C₄H₂F₆, E-isomer and Z-isomer), perfluorocyclopentene (C₅F₈), hexafluorobenzene (C₆F₆), octafluorotoluene (C₇F₈), and the like.

Among the halogen-containing compounds, chlorine gas, nitrogen trifluoride, sulfur hexafluoride, tetrafluoromethane, octafluorocyclobutane, trifluoromethane, difluoromethane, and hexafluoro-1,3-butadiene are preferable, and chlorine gas, nitrogen trifluoride, sulfur hexafluoride, tetrafluoromethane, difluoromethane, and hexafluoro-1,3-butadiene are more preferable from the viewpoint of ease of accessibility.

The concentration of the halogen-containing compound contained in the etching gas is not particularly limited. Depending on the type of the halogen-containing compound, the concentration of the halogen-containing compound contained in the etching gas can be set to 0% by volume or more and less than 100% by volume, for example, and is preferably more than 0% by volume and 30% by volume or less, more preferably 3% by volume or more and 25% by volume or less, and still more preferably 10% by volume or more and 20% by volume or less.

Examples of the oxygen-containing compound include oxygen gas (O₂), ozone (O₃), nitrous oxide (N₂O), nitrogen monoxide (NO), nitrogen dioxide (NO₂), and sulfur trioxide (SO₃). As described above, the film of the compound having a carbon-sulfur bond derived from the fluoro-dithiethane is formed on the surface of the carbon material during etching. The addition of the oxygen-containing compound to the etching gas sometimes suppresses excessive deposition of the film of the compound. Depending on the type of the oxygen-containing compound, the concentration of the oxygen-containing compound contained in the etching gas can be set to 0% by volume or more and 30% by volume or less, for example, and is preferably set to more than 0% by volume and 20% by volume or less and more preferably set to 3% by volume or more and 10% by volume or less.

The type of the inert gas is not particularly limited insofar as it hardly reacts with the fluoro-dithiethane or the second etching compound under a condition where no plasma is generated. Examples of the inert gas include rare gases, such as helium (He), neon (Ne), argon (Ar), krypton (Kr), and xenon (Xe). Among the inert gases, helium and argon are preferable and argon is more preferable from the viewpoint of ease of accessibility. The inert gases may be used alone or in combination of two or more types thereof.

By adding the inert gas, such effects that the plasma is likely to be stabilized and uniform plasma is likely to be obtained are likely to be exhibited. The concentration of the inert gas contained in the etching gas can be set to 0% by volume or more and less than 100% by volume, for example, and is preferably 30% by volume or more and 95% by volume or less, more preferably 50% by volume or more and 90% by volume or less, and still more preferably 60% by volume or more and 80% by volume or less.

The etching gas can be obtained by mixing the plurality of components (etching compound, second etching compound, inert gas, and the like) constituting the etching gas. The mixing of the plurality of components may be performed either inside or outside a chamber where etching is performed. More specifically, the plurality of components constituting the etching gas may be individually and independently introduced into a chamber and mixed in the chamber, or the plurality of components constituting the etching gas may be mixed to obtain the etching gas and the obtained etching gas may be introduced into a chamber.

The etching gas also sometimes contains impurities. The impurities are components different from the etching compound and the other type of gas among the components of the etching gas. The impurities that can be contained in the etching gas include impurity gases, such as water (H₂O), hydrogen fluoride (HF), hydrogen chloride (HCl), hydrogen sulfide (H₂S), and sulfur dioxide (SO₂), and metals, for example. The metals are described in detail later.

Water (water vapor), hydrogen fluoride, hydrogen chloride, hydrogen sulfide, and sulfur dioxide that are the above-described impurity gases have a risk of corroding gas pipes for sending the gases, a chamber where etching is performed, a storage container for the fluoro-dithiethane, and the like. Thus, the impurity gas is preferably removed as much as possible from the etching gas. Thus, the reproducibility of the etching is likely to increase.

However, excessive purification performed to remove the impurity gas from the etching gas leads to an increase in the production cost of the etching gas, and therefore a small amount of the impurity gas may be contained in the etching gas. The concentration of the impurity gas in the etching gas is preferably 1% by volume or less, more preferably 1000 ppm by volume or less, and still more preferably 100 ppm by volume or less.

### [Metal]

When metal is present in the etching gas, the metal sometimes remains on the surface of the carbon material and is bonded with the sulfur atom derived from the fluoro-dithiethane. The bonding between the metal and the sulfur atom derived from the fluoro-dithiethane poses risks of the insufficient formation of a bond between the carbon atom on the surface of the carbon material and the sulfur atom derived from the fluoro-dithiethane or the alternation of the proportion of activated species generated from the fluoro-dithiethane.

As a result, the carbon material is likely to be etched or the etching rate of the silicon material decreases, which poses a risk of a decrease in the etching selectivity, which is the ratio of the etching rate of the silicon material to the etching rate of the carbon material. Accordingly, the concentration of the metal in the etching gas is preferably as low as possible. When the etching gas or the etching compound contains metal, the metal is preferably removed as much as possible by purification. As a method for removing the metal, common purification methods, such as distillation, sublimation, filtration, membrane separation, adsorption, and recrystallization, are usable.

The types of metals whose concentrations are to be reduced include metal elements belonging to the 3 to 6 periods of the periodic table, and include sodium, magnesium, aluminum, potassium, calcium, chromium, manganese, iron, cobalt, nickel, copper, zinc (Zn), antimony (Sb), molybdenum, and tungsten (W), for example.

Among these metals, sodium, magnesium, aluminum, potassium, calcium, chromium, manganese, iron, cobalt, nickel, copper, and molybdenum are contained in raw materials of members (e.g., metal pipe, storage container) with which the etching gas comes into contact in many cases, and therefore are likely to be mixed into the etching gas.

Thus, the etching gas contains or does not contain at least one type of metal among sodium, magnesium, aluminum, potassium, calcium, chromium, manganese, iron, cobalt, nickel, copper, and molybdenum as impurities. When the etching gas contains the at least one type of metal, the total concentration of all types of the contained metals is required to be set to 300 ppb by mass or less.

Thus, the etching selectivity, which is the ratio of the etching rate of the silicon material to the etching rate of the carbon material, increases. For example, when the etching gas which contains the fluoro-dithiethane and in which the total concentration of all types of the contained metals is 300 ppb by mass or less is used, the etching selectivity, which is the ratio of the etching rate of the silicon material to the etching rate of the carbon material, is sometimes improved by a factor of 1.1 or more as compared with a case where an etching gas which contains the fluoro-dithiethane and in which the total concentration of all types of the contained metals is more than 300 ppb by mass is used, depending on the type of the fluoro-dithiethane to be used. When preferable conditions are satisfied, the etching selectivity is sometimes improved by a factor of 1.2 or more. When more preferable conditions are satisfied, the etching selectivity is sometimes improved by a factor of 1.3 or more.

There is a possibility that these metals are contained in the etching gas in the form of a simple substance and/or a metal compound. The metal compound means a compound having a metal element, and includes metal oxide, metal nitride, metal oxynitride, metal chloride, metal bromide, metal iodide, metal sulfide, and the like, for example.

The concentration of the metal in the etching gas can be quantified with an inductively coupled plasma mass spectrometer (ICP-MS). Herein, the “does not contain metal” means that the metal cannot be quantified with an inductively coupled plasma mass spectrometer (ICP-MS).

The total concentration of all types of the metals contained in the etching gas is preferably 1 ppb by mass or more and 300 ppb by mass or less, more preferably 5 ppb by mass or more and 200 ppb by mass or less, and still more preferably 10 ppb by mass or more and 100 ppb by mass or less.

### [Member to be Etched]

The member to be etched subjected to etching by the etching method according to this embodiment has an etching object subject to etching by the etching gas and a non-etching object not subject to etching by the etching gas. The etching object has a silicon material and the non-etching object has a carbon material.

The member to be etched may be a member having a portion formed of the etching object and a portion formed of the non-etching object or may be a member formed of a mixture of the etching object and the non-etching object. The member to be etched may further have one other than the etching object and the non-etching object.

The shape of the member to be etched is not particularly limited and may be a plate shape, a foil shape, a film shape, a powder shape, or a block shape, for example. Examples of the member to be etched include the above-described semiconductor substrate.

### [Etching Object]

The etching object has a silicon material and may be one formed of only a silicon material, may be one having a portion formed of only a silicon material and a portion formed of other materials, or may be one formed of a mixture of a silicon material and other materials. The shape of the etching object is not particularly limited and may be a plate shape, a foil shape, a film shape, a powder shape, or a block shape, for example.

The silicon material refers to a material having silicon (Si) in a proportion of 10% by mol or more and 100% by mol or less in the composition, and preferably has silicon in a proportion of 20% by mol or more and 100% by mol or less and more preferably has silicon in a proportion of 30% by mol or more and 100% by mol or less. The silicon material may have elements, such as hydrogen (H), carbon (C), nitrogen (N), oxygen (O), and germanium (Ge), in addition to silicon.

Examples of such a silicon material include monocrystalline silicon, polysilicon, amorphous silicon, silicon nitride, silicon oxide, silicon oxynitride (SiON), and silicon germanium (SiₜGe₁₀₀₋ₜ, wherein t is a coefficient). Among these silicon materials, silicon compounds and polysilicon are preferable. Herein, the silicon compound is a compound having at least one of an oxygen atom and a nitrogen atom, and a silicon atom, and includes silicon nitride, silicon oxide, and silicon oxynitride, for example.

Examples of the silicon oxide include silicon dioxide (SiO₂). Silicon nitride refers to a compound having silicon and nitrogen in an optional proportion, and includes Si₃N₄, for example. The purity of silicon nitride is not particularly limited, and is preferably 30% by mass or more, more preferably 60% by mass or more, and still more preferably 90% by mass or more.

The silicon materials may be used alone or in combination of two or more types thereof. The chemical formula representing silicon germanium is given above, but is merely one example. It is easy for those skilled in the art to imagine that the chemical composition or the coefficient varies depending on the film formation conditions and the raw materials to be used.

### [Non-Etching Object]

The non-etching object does not substantially react with the above-described etching compound or extremely slowly reacts with the above-described etching compound. Therefore, even when etching is performed by the etching method according to this embodiment, the etching hardly progresses.

The non-etching object has a carbon material and may be one formed of only a carbon material, may be one having a portion formed of only a carbon material and a portion formed of other materials, or may be one formed of a mixture of a carbon material and other materials. The shape of the non-etching object is not particularly limited and may be a plate shape, a foil shape, a film shape, a powder shape, or a block shape, for example.

The carbon material refers to a material having carbon in a proportion of 20% by mass or more and 100% by mass or less in the composition, and preferably has carbon in a proportion of 50% by mass or more and 100% by mass or less and more preferably has carbon in a proportion of 60% by mass or more and 100% by mass or less. The carbon material may have elements other than carbon.

Examples of such a carbon material include amorphous carbon, carbon-added silicon oxide, and a photoresist. Among these carbon materials, amorphous carbon and a photoresist are preferable. The carbon materials may be used alone or in combination of two or more types thereof.

The non-etching object is usable as a resist or a mask for suppressing the etching of the etching object by the etching gas. Thus, the etching method according to this embodiment can be utilized for a method including processing the etching object into a predetermined shape (e.g., processing the etching object in a film shape possessed by the member to be etched to have a predetermined film thickness) utilizing the non-etching object subjected to patterning as the resist or the mask, for example, and therefore is suitably usable for the manufacture of semiconductor elements. The non-etching object is hardly etched, and therefore etching of a portion that should not be essentially etched of a semiconductor element can be suppressed and the loss of the characteristics of a semiconductor element by etching can be prevented.

A method for forming the carbon material is not particularly restricted, and methods commonly used for forming the carbon material into a film, e.g., spray coating, spin coating, thermal chemical vapor deposition (CVD), plasma enhanced chemical vapor deposition (PECVD), and the like, are usable. In particular, the PECVD using a hydrocarbon precursor is commonly used in a method for forming amorphous carbon into a film. The type of the hydrocarbon precursor is not particularly restricted, and alkane, alkene, and alkyne are all usable.

More specifically, the hydrocarbon precursor includes methane (CH₄), ethane (C₄H₆), ethylene (C₂H₄), propylene (C₃H₆), propyne (C₃H₄), propane (C₃H₈), butane (C₄H₁₀), butene (C₄H₈, including isomers), butadiene (C₄H₆), acetylene (C₂H₂), toluene (CH₈), and mixtures thereof.

### [Temperature Condition of Etching Step]

A temperature condition of the etching step in the etching method according to this embodiment is not particularly limited. The temperature of the member to be etched in etching is preferably set to −60° C. or more and 100° C. or less, more preferably set to −40° C. or more and 80° C. or less, still more preferably set to −20° C. or more and 60° C. or less, and particularly preferably set to 10° C. or more and 40° C. or less. When etching is performed with the temperature of the member to be etched set in the ranges above, the etching selectivity is likely to increase.

### [Pressure Condition of Etching Step]

A pressure condition of the etching step in the etching method according to this embodiment is not particularly limited. The pressure in a chamber where etching is performed is preferably set to 0.1 Pa or more and 100 Pa or less, more preferably set to 0.5 Pa or more and 20 Pa or less, and still more preferably set to 1 Pa or more and 10 Pa or less. When the pressure condition is in the ranges above, plasma is likely to be stabilized and uniform plasma is likely to be obtained.

The usage amount of the etching gas in the etching method according to this embodiment, e.g., the total flow rate of the etching gas to a chamber where plasma etching is performed in a plasma etching device, may be adjusted according to the internal volume of the chamber, the capability of an exhaust facility reducing the pressure inside the chamber, the pressure in the chamber, and the like.

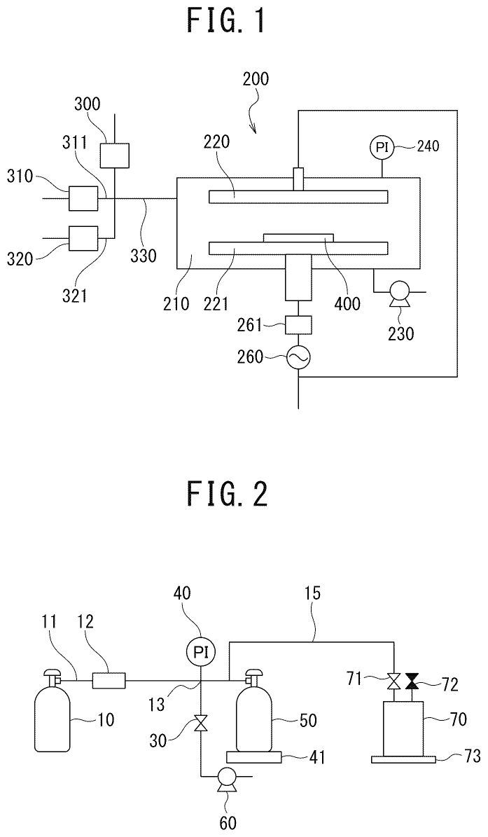

Next, one example of the configuration of an etching device capable of implementing the etching method according to this embodiment and one example of an etching method using the etching device are described with reference to FIG. 1. The etching device in FIG. 1 is a plasma etching device performing etching using capacitively coupled plasma as a plasma source. First, the etching device in FIG. 1 is described.

An etching device 200 in FIG. 1 includes a chamber 210 inside which plasma etching is performed, an upper electrode 220 forming an electric field and a magnetic field for converting the etching gas into plasma inside the chamber 210, a lower electrode 221 supporting a member to be etched 400 to be subjected to plasma etching inside the chamber 210, a vacuum pump 230 reducing the pressure inside the chamber 210, and a pressure gauge 240 measuring the pressure inside the chamber 210.

To the upper electrode 220 and the lower electrode 221, a high frequency power supply 260 generating high frequency waves is connected. The lower electrode 221 and the high frequency power supply 260 are connected via a matching device 261. The matching device 261 has a circuit to match an output impedance of the high frequency power supply 260 with impedances of the upper electrode 220 and the lower electrode 221. To the upper electrode 220 and the lower electrode 221, high frequency power supplies having different frequencies may be individually connected. In such a case, both the connection between the upper electrode 220 and the high frequency power supply and the connection between the lower electrode 221 and the high frequency power supply are preferably performed via the matching device.

The etching device 200 in FIG. 1 includes an etching gas supply section supplying an etching gas into the chamber 210. The etching gas supply section has a fluoro-dithiethane gas supply section 300 supplying a fluoro-dithiethane gas, an inert gas supply section 310 supplying an inert gas, a second etching compound gas supply section 320 supplying a second etching compound gas, an etching gas supply pipe 330 connecting the fluoro-dithiethane gas supply section 300 and the chamber 210, an inert gas supply pipe 311 connecting the inert gas supply section 310 to an intermediate part of the etching gas supply pipe 330, and a second etching compound gas supply pipe 321 connecting the second etching compound gas supply section 320 to the intermediate part of the etching gas supply pipe 330.

When the fluoro-dithiethane gas is supplied as an etching gas to the chamber 210, the fluoro-dithiethane gas is sent from the fluoro-dithiethane gas supply section 300 to the etching gas supply pipe 330, so that the fluoro-dithiethane gas is supplied to the chamber 210 via the etching gas supply pipe 330.

The pressure in the chamber 210 before the etching gas is supplied is not particularly limited insofar as it is equal to or less than the supply pressure of the etching gas or lower than the supply pressure of the etching gas. For example, the pressure is preferably 10⁻⁵ Pa or more and less than 100 kPa and more preferably 1 Pa or more and 80 kPa or less.

When a mixed gas of the fluoro-dithiethane gas and the inert gas is suppled as the etching gas to the chamber 210, the fluoro-dithiethane gas is sent from the fluoro-dithiethane gas supply section 300 to the etching gas supply pipe 330 and the inert gas is sent from the inert gas supply section 310 to the intermediate part of the etching gas supply pipe 330 via the inert gas supply pipe 311. Thus, the fluoro-dithiethane gas and the inert gas are mixed to form a mixed gas in the intermediate part of the etching gas supply pipe 330, and the mixed gas is supplied to the chamber 210 via the etching gas supply pipe 330.

Further, by performing the same operation as above, a mixed gas of the fluoro-dithiethane gas and the second etching compound gas or a mixed gas of the fluoro-dithiethane gas, the second etching compound gas, and the inert gas can be supplied as the etching gas to the chamber 210.

To facilitate the vaporization of the fluoro-dithiethane, the fluoro-dithiethane gas supply section 300 may be heated with an external heater (not illustrated) or the like and, to prevent the liquefication of the etching gas containing the fluoro-dithiethane in the pipe, the inert gas supply pipe 311, the second etching compound gas supply pipe 321, and the etching gas supply pipe 330 may be heated with an external heater (not illustrated) or the like.

When plasma etching is performed using such an etching device 200, the member to be etched 400 is placed on the lower electrode 221 arranged inside the chamber 210, the pressure inside the chamber 210 is reduced with the vacuum pump 230, and then the etching gas is supplied into the chamber 210 with the etching gas supply section. Then, when a high frequency power is applied to the upper electrode 220 and the lower electrode 221 with the high frequency power supply 260, an electric field and a magnetic field are formed inside the chamber 210, which accelerates electrons. The accelerated electrons collide with the fluoro-dithiethane and the like in the etching gas to generate new ions and electrons, and, as a result, discharge occurs and plasma is formed.

When the plasma is generated, the member to be etched 400 is etched. The supply amount of the etching gas to the chamber 210 and the concentration of the fluoro-dithiethane in the etching gas (mixed gas) can be adjusted by controlling the flow rates of the fluoro-dithiethane gas, the second etching compound gas, and the inert gas with mass flow controllers (not illustrated) placed in the etching gas supply pipe 330, the second etching compound gas supply pipe 321, and the inert gas supply pipe 311, respectively.

### EXAMPLES

Hereinafter, the present invention is more specifically described with reference to Examples and Comparative Examples below. Fluoro-dithiethane gases and second etching compound gases containing various concentrations of metals were individually prepared. Preparation examples of the fluoro-dithiethane gases and the second etching compound gases are described below.

### Preparation Example 1

The fluoro-dithiethane was purified using a purification device illustrated in FIG. 2. A raw material container 10 (formed of manganese steel, 3 L capacity) filled with 1 kg of 2,2,4,4-tetrafluoro-1,3-dithietane is connected to the inlet side of a gas filter 12 (Wafergard (registered trademark) manufactured by Entegris, Inc.) via a SUS 316 pipe 11. The raw material container 10 is attached with a main cock.

The outlet side of the gas filter 12 is connected to one branch pipe of a SUS316 branch pipe 13 branching in the shape of a cross. The other three branch pipes of the branch pipe 13 are individually connected to a vacuum pump 60, a vacuum gauge 40, and a receiving container 50 (formed of manganese steel, 3 L capacity). The raw material container 10, the pipe 11, and the branch pipe 13 can be heated to an optional temperature with an external heater (not illustrated).

An intermediate part of the branch pipe to which the vacuum pump 60 is connected is provided with a vacuum pump valve 30. The receiving container 50 is a container storing the fluoro-dithiethane purified by being passed through the gas filter 12 and is placed on a receiving container mass meter 41 measuring the mass of the receiving container 50. The receiving container 50 is attached with a main cock.

A branch pipe 15 extends from an intermediate part of the branch pipe to which the receiving container 50 is connected and is connected to a vaporizer 70 (formed of manganese steel, 30 mL capacity). The vaporizer 70 is a container storing the fluoro-dithiethane purified by being passed through the gas filter 12 and is placed on a vaporizer mass meter 73 measuring the mass of the vaporizer 70. The vaporizer 70 is attached with an inlet vaporizer valve 71 and an outlet vaporizer valve 72. The inlet vaporizer valve 71 is connected to the branch pipe 15 and the outlet vaporizer valve 72 is constantly closed.

The raw material container 10 was heated to 70° C., the pipe 11, the branch pipe 13, and the branch pipe 15 were heated to 100° C., the main cock of the raw material container 10 was closed, and the main cock of the receiving container 50 and the inlet vaporizer valve 71 were opened. Then, the vacuum pump valve 30 was opened, and the pressure inside the pipe 11, the branch pipe 13, the branch pipe 15, the receiving container 50, and the vaporizer 70 was reduced with the vacuum pump 60 until the pressure reached 10 Pa or less.

Thereafter, the vacuum pump valve 30 was closed, the main cock of the raw material container 10 and a main valve of the branch pipe 13 were opened, and 500 g of the 2,2,4,4-tetrafluoro-1,3-dithietane was sent to the receiving container 50 and 10 g of the 2,2,4,4-tetrafluoro-1,3-dithietane was sent to the vaporizer 70 from the raw material container 10. The 2,2,4,4-tetrafluoro-1,3-dithietane that was unpurified in the raw material container 10 is designated as Sample 1-1, and the 2,2,4,4-tetrafluoro-1,3-dithietane subjected to purification treatment and filled into the receiving container 50 and the vaporizer 70 is designated as Sample 1-2. Sample 1-2 was further purified by the same operation as above. The 2,2,4,4-tetrafluoro-1,3-dithietane subjected to the purification treatment twice is designated as Sample 1-3.

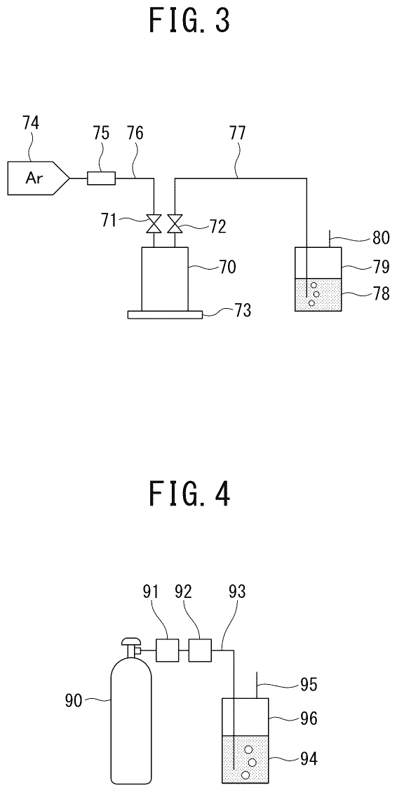

The concentrations of metals (M) contained in Sample 1-2 and Sample 1-3 were determined as follows. First, a mixed liquid of the fluoro-dithiethane and an aqueous nitric acid solution was prepared using a preparation device illustrated in FIG. 3. A method for preparing the mixed liquid is described below. The vaporizer 70 filled with the purified fluoro-dithiethane was removed from the purification device in FIG. 2 and attached to the preparation device in FIG. 3. More specifically, the inlet vaporizer valve 71 of the vaporizer 70 is connected to a mass flow controller 75 and an argon supply section 74 via an argon pipe 76, and the outlet vaporizer valve 72 is connected to a nitric acid container 79 via a connection pipe 77. The nitric acid container 79 stores 40 g of an aqueous nitric acid solution 78 having a concentration of 1% by mass. The tip of the connection pipe 77 is arranged in the aqueous nitric acid solution 78. The nitric acid container 79 is provided with an exhaust port 80.

The vaporizer 70 was heated to 80° C. with an external heater (not illustrated) and the connection pipe 77 was heated to 100° C. with an external heater (not illustrated). Then, argon at a flow rate of 40 mL/min was supplied from the argon supply section 74 to the vaporizer 70 via the argon pipe 76 for bubbling of the fluoro-dithiethane in the vaporizer 70 in the aqueous nitric acid solution 78 in the nitric acid container 79. After the bubbling was completed, the mass of the vaporizer 70 was measured with the vaporizer mass meter 73. Then, the mass decreased by 10 g (A) as compared with the mass before the bubbling. Accordingly, it is supposed that the entire amount of the fluoro-dithiethane in the vaporizer 70 was vaporized and supplied to the aqueous nitric acid solution 78 in the nitric acid container 79.

Next, the aqueous nitric acid solution having a concentration of 1% by mass was added such that the mass of the substances stored in the nitric acid container 79 reached 50 g (B), giving a mixed liquid of the fluoro-dithiethane and the aqueous nitric acid solution. 1 g of an aqueous layer part of the mixed liquid was extracted and analyzed for metals using an inductively coupled plasma mass spectrometer to measure the signal intensities of sodium, magnesium, aluminum, potassium, calcium, chromium, manganese, iron, cobalt, nickel, copper, and molybdenum contained in the mixed liquid (y). Then, the concentrations of the metal were calculated from the signal intensities above using calibration curves, and were totalized, thereby determining the total concentration of the metals.

The used calibration curves were created as follows. More specifically, reference aqueous nitric acid solutions having metal concentrations of 0 ppb by mass (containing no metals), 10 ppb by mass, 100 ppb by mass, 300 ppb by mass, 700 ppb by mass, and 1200 ppb by mass were produced and analyzed using an inductively coupled plasma mass spectrometer. Then, a calibration curve was created in which the concentration of the metal was plotted on the horizontal axis and the signal intensity was plotted on the vertical axis, and the slope (a) and the intercept (b) of the calibration curve were determined. The same operation was performed for sodium, magnesium, aluminum, potassium, calcium, chromium, manganese, iron, cobalt, nickel, copper, and molybdenum to create the calibration curves of the metals.

The concentration M of the metal contained in the fluoro-dithiethane can be calculated by the following equation.

$$y = \{ ( y - b ) / a \} \times ( B / A )$$

The concentration of metal in the argon is less than the detection limit of the inductively coupled plasma mass spectrometer and the detection limit is 0.1 ppb by mass, and therefore the concentration of metal in the argon was disregarded.

Similarly, the unpurified fluoro-dithiethane (Sample 1-1) filled into the raw material container 10 was also determined for the concentrations of the contained metals and the total concentration thereof. The analysis results of Sample 1-1, Sample 1-2, and Sample 1-3 are shown in Table 1.

TABLE 1

| | Na | Mg | Al | K | Ca | Cr | Mn | Fe | Co | Ni | Cu | Mo | Total |
|---|---|---|---|---|---|---|---|---|---|---|---|---|---|
| Sample 1-1 | 32 | 17 | 31 | 39 | 38 | 211 | 101 | 189 | 121 | 98 | 75 | 101 | 1053 |
| Sample 1-2 | 6 | 8 | 6 | 6 | 6 | 43 | 21 | 55 | 13 | 11 | 11 | 12 | 198 |
| Sample 1-3 | 4 | 4 | 5 | 4 | 4 | 5 | 4 | 5 | 4 | 4 | 4 | 5 | 52 |
| Sample 2-1 | 41 | 34 | 43 | 25 | 27 | 258 | 98 | 171 | 144 | 101 | 81 | 121 | 1144 |
| Sample 2-2 | 4 | 4 | 3 | 4 | 3 | 5 | 5 | 4 | 4 | 4 | 4 | 4 | 48 |
| Sample 3-1 | 42 | 55 | 51 | 26 | 30 | 189 | 157 | 179 | 118 | 54 | 37 | 103 | 1041 |
| Sample 3-2 | 4 | 4 | 4 | 4 | 4 | 8 | 5 | 5 | 6 | 7 | 5 | 4 | 60 |
| Sample 4-1 | 27 | 55 | 55 | 31 | 37 | 257 | 198 | 157 | 96 | 22 | 76 | 88 | 1099 |
| Sample 4-2 | 4 | 4 | 4 | 5 | 4 | 5 | 4 | 6 | 4 | 5 | 4 | 4 | 53 |
| Sample 5-1 | 32 | 12 | 23 | 11 | 26 | 251 | 108 | 110 | 83 | 91 | 101 | 161 | 1009 |
| Sample 5-2 | 4 | 4 | 4 | 5 | 4 | 4 | 5 | 4 | 4 | 4 | 4 | 4 | 50 |
| Sample 6-1 | 12 | 10 | 57 | 10 | 7 | 101 | 206 | 99 | 141 | 101 | 87 | 212 | 1043 |
| Sample 6-2 | 4 | 4 | 4 | 4 | 5 | 4 | 4 | 5 | 5 | 4 | 5 | 4 | 52 |

*) Unit of numerical values is ppb by mass.

### Preparation Example 2 to 5

Each fluoro-dithiethane was purified, and the unpurified fluoro-dithiethane and the purified fluoro-dithiethane were determined for the concentrations of the contained metals and the total concentration thereof in the same manner as in the case of Preparation Example 1. The results are shown in Table 1.

The fluoro-dithiethane of Preparation Example 2 is 1,1,2,2,3,3,4,4-octafluoro-1,3-dithietane. The unpurified product is designated as Sample 2-1 and the purified product is designated as Sample 2-2. The fluoro-dithiethane of Preparation Example 3 is 2,2,4-trifluoro-4-trifluoromethyl-1,3-dithietane. The unpurified product is designated as Sample 3-1 and the purified product is designated as Sample 3-2.

The fluoro-dithiethane of Preparation Example 4 is 2,4-difluoro-2,4-bis(trifluoromethyl)-1,3-dithietane. The unpurified product is designated as Sample 4-1 and the purified product is designated as Sample 4-2. The fluoro-dithiethane of Preparation Example 5 is 2,2,4,4-tetrakis(trifluoromethyl)-1,3-dithietane. The unpurified product is designated as Sample 5-1 and the purified product is designated as Sample 5-2.

### Preparation Example 6

Sulfur hexafluoride of SynQuest Laboratories was purified using the purification device illustrated in FIG. 2 in the same manner as in the case of Preparation Example 1. The unpurified product is designated as Sample 6-1 and the purified product is designated as Sample 6-2.

The concentrations of the metals contained in Sample 6-2 and the total concentration thereof were determined in the same manner as in the case of Preparation Example 1. The concentrations of the metal contained in Sample 6-1 and the total concentration thereof were determined as follows. First, a mixed liquid of sulfur hexafluoride and an aqueous nitric acid solution was prepared using a preparation device illustrated in FIG. 4. A method for preparing the mixed liquid is described below. A main valve of the container 90 filled with 50 g of sulfur hexafluoride is connected to a nitric acid container 96 via a connection pipe 93. The nitric acid container 96 stores 100 mL of an aqueous nitric acid solution 94 having a concentration of 1% by mass. The tip of the connection pipe 93 is arranged in the aqueous nitric acid solution 94. The nitric acid container 96 is provided with an exhaust port 95. Further, a pressure regulator 91 and a mass flow controller 92 are placed in an intermediate part of the connection pipe 93.

The main valve of the container 90 was opened, and sulfur hexafluoride gas was bubbled in the aqueous nitric acid solution 94 in the nitric acid container 96 via the connection pipe 93 while the supply pressure and the flow rate were controlled with the pressure regulator 91 and the mass flow controller 92, respectively, and then discharged through the exhaust port 95. The pressure in bubbling was set to 0.1 MPa in terms of gauge pressure and the flow rate was set to 100 mL/min, and the bubbling was continued until 10 g of the sulfur hexafluoride was bubbled. This gave the mixed liquid of the sulfur hexafluoride and the aqueous nitric acid solution. The mixed liquid thus prepared was analyzed in the same manner as in the case of Preparation Example 1 to determine the concentrations of the metals contained in Sample 6-1 and the total concentration thereof. The results are shown in Table 1.

### Example 1

Five types of etching test pieces were simultaneously subjected to plasma etching using an ICP etching device RIE-200iP manufactured by Samco, Inc. The five types of etching test pieces are one obtained by forming a polysilicon (Poly-Si) film having a film thickness of 2000 nm on a silicon substrate (manufactured by SEIREN KST Corp.), one obtained by forming a silicon dioxide film having a film thickness of 1000 nm on a silicon substrate (manufactured by SEIREN KST Corp.), one obtained by forming a silicon nitride (Si₃N₄) film having a film thickness of 1000 nm on a silicon substrate (manufactured by SEIREN KST Corp.), one obtained by forming a photoresist film having a film thickness of 1000 nm on a silicon substrate, and one obtained by forming an amorphous carbon film having a film thickness of 1000 nm on a silicon substrate (APF (registered trademark) manufactured by Applied Materials, Inc.).

The photoresist film was formed by applying a photoresist TSCR (registered trademark) manufactured by TOKYO OHKA KOGYO CO., LTD. on a silicon substrate, followed by exposure and curing. The silicon substrates used in the five types of etching test pieces all have square shapes of, 2 cm on each side.

Next, conditions of the plasma etching are described. The volume of a chamber of the ICP etching device is 46000 cm³. The etching gas is a mixed gas of the 2,2,4,4-tetrafluoro-1,3-dithietane of Sample 1-3 and argon. The concentration of the 2,2,4,4-tetrafluoro-1,3-dithietane in the etching gas in the chamber was adjusted to 20% by volume by setting the flow rate of Sample 1-3 to be introduced into the chamber to 20 mL/min and the flow rate of the argon to be introduced into the chamber to 80 mL/min. The concentration of metal contained in the argon used herein was less than the detection limit.

The total concentration of the metals in the etching gas at this time was calculated by the following formula.

$$Total concentration of metals in etching gas = {M}_{1} \times {V}_{1} \times {X}_{1} / ( {M}_{1} \times {V}_{1} + {M}_{2} \times {V}_{2} )$$

In the equation, M₁ is the molecular weight of the fluoro-dithiethane, M₂ is the atomic weight of the inert gas (argon), V₁ is the flow rate of the fluoro-dithiethane gas, V₂ is the flow rate of the inert gas, and X₁ is the total concentration of the metals contained in the fluoro-dithiethane.

The pressure inside the chamber was set to 3 Pa, the source power was set to 400 W, the bias power was set to 200 W, and the temperature of the etching test piece was set to 20° C., and then plasma etching was performed while the flow rate of 2,2,4,4-tetrafluoro-1,3-dithietane gas, the flow rate of the argon, the pressure, the source power, the bias power, and the temperature of the etching test piece were constantly monitored to ensure that there was no difference between the set values and the run values thereof.

When the etching was completed, the etching test piece was taken out from the chamber, the film thickness of each film formed on the silicon substrate was measured, and the etching rate of each film was calculated. The film thickness was measured using a F20 reflectance spectrometer for film thickness measurement manufactured by Filmetrics. The etching rate of each film was calculated by subtracting the film thickness after etching from the film thickness before etching and dividing the resultant value by etching time. The results are shown in Table 2.

The conditions for measuring the film thickness are as follows. More specifically, the measurement atmosphere is air and the measurement temperature is 25° C. The measurement wavelength range is a wavelength range where the goodness of fit is 0.9 or more. Specifically, the following wavelength ranges were set as a standard. More specifically, the measurement wavelengths are 500 to 1200 nm for the polysilicon, 300 to 1100 nm for the silicon dioxide, 500 to 1500 nm for the silicon nitride, 400 to 1000 nm for the photoresist, and 400 to 800 nm for the amorphous carbon.

Then, the etching selectivity was calculated from the etching rate of each film determined as described above. More specifically, the ratio of the etching rate of the polysilicon to the etching rate of the photoresist (Etching rate of polysilicon/Etching rate of photoresist), the ratio of the etching rate of the silicon dioxide to the etching rate of the photoresist (Etching rate of silicon dioxide/Etching rate of photoresist), and the ratio of the etching rate of the silicon nitride to the etching rate of the photoresist (Etching rate of silicon nitride/Etching rate of photoresist) were calculated.

The ratio of the etching rate of the polysilicon to the etching rate of the amorphous carbon (Etching rate of polysilicon/Etching rate of amorphous carbon), the ratio of the etching rate of the silicon dioxide to the etching rate of the amorphous carbon (Etching rate of silicon dioxide/Etching rate of amorphous carbon), and the ratio of the etching rate of the silicon nitride to the etching rate of the amorphous carbon (Etching rate of silicon nitride/Etching rate of amorphous carbon) were also calculated. The results are shown in Table 2.

TABLE 2

| | Etching gas | | | | | | | | |
|---|---|---|---|---|---|---|---|---|---|
| | | Second | | Flow | Metal | Etching rate (nm/min) ²⁾ | | | |
| | Fluoro- | etching | Inert | rate ¹⁾ | (ppb by | | Silicon | Silicon | |
| | dithiethane | compound | gas | (mL/min) | mass) | Polysilicon | nitride | oxide | |
| Ex. 1 | Sample 1-3 | None | Ar | 20/0/80 | 26 | 47 | 53 | 80 | |
| Ex. 2 | Sample 2-2 | None | Ar | 20/0/80 | 29 | 85 | 106 | 110 | |
| Ex. 3 | Sample 3-2 | None | Ar | 20/0/80 | 34 | 70 | 112 | 92 | |
| Ex. 4 | Sample 4-2 | None | Ar | 20/0/80 | 33 | 72 | 111 | 109 | |
| Ex. 5 | Sample 5-2 | None | Ar | 20/0/80 | 35 | 91 | 172 | 95 | |
| Ex. 6 | Sample 1-2 | None | Ar | 20/0/80 | 100 | 47 | 47 | 82 | |
| Ex. 7 | Sample 1-1 + 1-2 ³⁾ | None | Ar | 20/0/80 | 273 | 48 | 51 | 85 | |
| Comp. Ex. 1 | Sample 1-1 | None | Ar | 20/0/80 | 533 | 49 | 53 | 92 | |
| Comp. Ex. 2 | Sample 2-1 | None | Ar | 20/0/80 | 687 | 73 | 112 | 83 | |
| Comp. Ex. 3 | Sample 3-1 | None | Ar | 20/0/80 | 596 | 86 | 93 | 103 | |
| Comp. Ex. 4 | Sample 4-1 | None | Ar | 20/0/80 | 684 | 65 | 105 | 89 | |
| Comp. Ex. 5 | Sample 5-1 | None | Ar | 20/0/80 | 701 | 72 | 168 | 97 | |
| Ex. 8 | Sample 1-3 | CF₄ | Ar | 10/20/70 | 14 | 44 | 66 | 53 | |
| Ex. 9 | Sample 1-3 | NF₃ | Ar | 15/15/70 | 20 | 113 | 53 | 46 | |
| Ex. 10 | Sample 1-3 | Sample 6-2 | Ar | 10/20/70 | 32 | 206 | 45 | 53 | |
| Ex. 11 | Sample 1-3 | CH₂F₂ | Ar | 10/20/70 | 16 | 52 | 122 | 55 | |
| Ex. 12 | Sample 1-3 | Cl₂ | Ar | 10/20/70 | 15 | 131 | 32 | 37 | |
| Ex. 13 | Sample 1-3 | C₄F₆ | Ar | 10/20/70 | 11 | 25 | 42 | 87 | |
| Ex. 14 | Sample 1-3 | c-C₄F₈ | Ar | 10/20/70 | 10 | 32 | 28 | 355 | |
| Ex. 15 | Sample 1-3 | H₂ | Ar | 20/3/77 | 27 | 32 | 91 | 51 | |
| Comp. Ex. 6 | None | CF₄ | Ar | 0/20/80 | Less than 2 | 56 | 72 | 60 | |
| Comp. Ex. 7 | None | NF₃ | Ar | 0/15/85 | Less than 2 | 121 | 62 | 21 | |
| Comp. Ex. 8 | None | Sample 6-2 | Ar | 0/20/80 | 25 | 237 | 31 | 4 | |
| Comp. Ex. 9 | None | CH₂F₂ | Ar | 0/20/80 | Less than 2 | 52 | 151 | 48 | |
| Comp. Ex. 10 | None | Cl₂ | Ar | 0/20/80 | Less than 2 | 95 | 20 | 13 | |
| Comp. Ex. 11 | None | C₄F₆ | Ar | 0/20/80 | Less than 2 | 9 | 53 | 90 | |
| Comp. Ex. 12 | None | c-C₄F₈ | Ar | 0/20/80 | Less than 2 | 13 | 26 | 380 | |
| Ref. Ex. 1 | None | Sample 6-1 | Ar | 0/20/80 | 498 | 210 | 33 | 4 | |
| | | Etching rate | | Etching selectivity | | | | | |
| | | (nm/min) ²⁾ | | | Silicon | Silicon | Polysilicon/ | Silicon nitride/ | Silicon oxide/ |
| | | | Amorphous | Polysilicon/ | nitride/ | oxide/ | Amorphous | Amorphous | Amorphous |
| | | Photoresist | carbon | Photoresist | Photoresist | Photoresist | carbon | carbon | carbon |
| | Ex. 1 | 2 | 1 | 24 | 27 | 40 | 47 | 53 | 80 |
| | Ex. 2 | 3 | 3 | 28 | 35 | 37 | 28 | 35 | 37 |
| | Ex. 3 | 4 | 2 | 18 | 28 | 23 | 35 | 56 | 46 |
| | Ex. 4 | −6 | −9 | — | — | — | — | — | — |
| | Ex. 5 | 4 | 2 | 23 | 43 | 24 | 46 | 86 | 48 |
| | Ex. 6 | 3 | 2 | 16 | 16 | 27 | 24 | 24 | 4 |
| | Ex. 7 | 3 | 2 | 16 | 17 | 28 | 24 | 26 | 43 |
| | Comp. Ex. 1 | 5 | 4 | 10 | 11 | 18 | 12 | 13 | 23 |
| | Comp. Ex. 2 | 8 | 6 | 9 | 14 | 10 | 12 | 19 | 14 |
| | Comp. Ex. 3 | 6 | 7 | 14 | 16 | 17 | 12 | 13 | 15 |
| | Comp. Ex. 4 | 8 | 6 | 8 | 13 | 11 | 11 | 18 | 15 |
| | Comp. Ex. 5 | 8 | 6 | 9 | 21 | 12 | 12 | 28 | 16 |
| | Ex. 8 | 28 | 21 | 2 | 2 | 2 | 2 | 3 | 3 |
| | Ex. 9 | 32 | 21 | 4 | 1.7 | 1.4 | 5 | 2.5 | 2.2 |
| | Ex. 10 | 28 | 26 | 7 | 2 | 2 | 8 | 2 | 2 |
| | Ex. 11 | 32 | 23 | 2 | 4 | 2 | 2 | 5 | 2 |
| | Ex. 12 | 19 | 16 | 7 | 2 | 2 | 8 | 2 | 2 |
| | Ex. 13 | 16 | 8 | 2 | 3 | 5 | 3 | 5 | 1 |
| | Ex. 14 | 18 | 21 | 2 | 2 | 20 | 2 | 1.3 | 17 |
| | Ex. 15 | −3 | −8 | — | — | — | — | — | — |
| | Comp. Ex. 6 | 78 | 75 | 1 | 0.9 | 0.8 | 0.7 | 1 | 0.8 |
| | Comp. Ex. 7 | 218 | 183 | 1 | 0.3 | 0.1 | 0.7 | 0.3 | 0.1 |
| | Comp. Ex. 8 | 55 | 38 | 4 | 0.6 | 0.1 | 6 | 0.8 | 0.1 |
| | Comp. Ex. 9 | 94 | 58 | 1 | 2 | 0.5 | 0.9 | 3 | 0.8 |
| | Comp. Ex. 10 | 58 | 37 | 2 | 0.3 | 0.2 | 3 | 0.5 | 0.4 |
| | Comp. Ex. 11 | 32 | 21 | 0.3 | 2 | 3 | 0.4 | 3 | 4 |
| | Comp. Ex. 12 | 33 | 34 | 0.4 | 0.8 | 12 | 0.4 | 0.8 | 11 |
| | Ref. Ex. 1 | 56 | 42 | 4 | 0.6 | 0.1 | 5 | 0.8 | 0.1 |

¹⁾ The flow rates are the flow rates of the fluoro-dithiethane, the second etching compound, and the inert gas. For example, a case where the flow rates of the fluoro-dithiethane, the second etching compound, and the inert gas are 20 mL, 0 mL, 80 mL, respectively, is indicated by “20/0/80”.
²⁾ A case where the etching rate is a negative value means the formation of a film containing a compound derived from the fluoro-dithiethane, and the numerical value indicates the deposition rate.
³⁾ Mixture of 40% by volume of Sample 1-1 and 60% by volume of Sample 1-2

### Examples 2 to 7 and Comparative Examples 1 to 5

Etching test pieces were etched by performing the same operation as in the case of Example 1, except that the fluoro-dithiethanes shown in Table 2 were used in place of the fluoro-dithiethane of Sample 1-3. Then, the etching rates of the silicon material and the carbon material were measured and the etching selectivity, which is the ratio of the etching rate of the silicon material to the etching rate of the carbon material, was calculated in the same manner as in the case of Example 1. The results are shown in Table 2.

### Examples 8 to 15

Etching test pieces were etched by performing the same operation as in the case of Example 1, except that the etching gases were mixed gases of the 2,2,4,4-tetrafluoro-1,3-dithietane of Sample 1-3, the second etching compound (tetrafluoromethane, nitrogen trifluoride, sulfur hexafluoride, difluoromethane, chlorine gas, hexafluoro-1,3-butadiene, octafluorocyclobutane, or hydrogen gas) gas shown in Table 2, and argon, and the flow rates of the three types of gases were as shown in Table 2. Then, the etching rates of the silicon material and the carbon material were measured and the etching selectivity, which is the ratio of the etching rate of the silicon material to the etching rate of the carbon material, was calculated in the same manner as in the case of Example 1. The results are shown in Table 2.

The total concentration of the metals in the etching gas was calculated by the following formula.

$$Total concentration of metals in etching gas = ( {M}_{1} \times {V}_{1} \times {X}_{1} + {M}_{3} \times {V}_{3} \times {X}_{3} ) / ( {M}_{1} \times {V}_{1} + {M}_{2} \times {V}_{2} + {M}_{3} \times {V}_{3} )$$

In the equation, M₁ is the molecular weight of the fluoro-dithiethane, M₂ is the atomic weight of the inert gas (argon), M₃ is the molecular weight of the second etching compound, V₁ is the flow rate of the fluoro-dithiethane gas, V₂ is the flow rate of the inert gas, V₃ is the flow rate of the second etching compound, X₁ is the total concentration of the metals contained in the fluoro-dithiethane, and X₃ is the total concentration of the metals contained in the second etching compound.

### Comparative Examples 6 to 12 and Reference Example 1

Etching test pieces were etched by performing the same operation as in the case of Example 1, except that the etching gas was a mixed gas of the second etching compound gas and argon, and the flow rates of the two types of gases were as shown in Table 2. Then, the etching rates of the silicon material and the carbon material were measured and the etching selectivity, which is the ratio of the etching rate of the silicon material to the etching rate of the carbon material, was calculated in the same manner as in the case of Example 1. The results are shown in Table 2.

The total concentration of the metals in the etching gas was calculated by the following formula.

$$Total concentration of metals in etching gas = {M}_{3} \times {V}_{3} \times {X}_{3} / ( {M}_{2} \times {V}_{2} + {M}_{3} \times {V}_{3} )$$

In the equation, M₂ is the atomic weight of the inert gas (argon), M₃ is the molecular weight of the second etching compound, V₂ is the flow rate of the inert gas, V₃ is the flow rate of the second etching compound, and X₃ is the total concentration of the metals contained in the second etching compound.

The results of Examples 1 to 7 and Comparative Examples 1 to 5 show the following facts. More specifically, by the use of the etching gas containing the fluoro-dithiethane and has a reduced concentration of metal, the etching rates of the photoresist, which is the carbon material, and amorphous carbon were lower than the etching rate of the silicon material or the film containing a compound derived from the fluoro-dithiethane was formed on the carbon material, so that the carbon material was not etched. As a result, the silicon material was selectively etched over the carbon material.

In Example 6 in which the etching gas having the total concentration of the contained metals of 100 ppb by mass was used and Example 7 in which the etching gas having the total concentration of the contained metals of 275 ppb by mass was used, the etching selectivity of the silicon material to the carbon material tended to slightly decrease as compared with those of the other examples in which the etching gas having the total concentration of the contained metals of less than 50 ppb by mass but were sufficiently high. On the other hand, when the etching gases having the total concentration of the contained metals of 500 ppb by mass or more (Comparative Examples 1 to 5) were used, the etching selectivity of the silicon material to the carbon material were low. These facts suggest that the removal of the metals, which are impurities, from the fluoro-dithiethane enables an increase in the etching selectivity of the silicon material to the carbon material.

The results of Examples 8 to 15 and Comparative Examples 6 to 12 show the following facts. More specifically, the etching selectivity of the silicon material to the carbon material were higher in Examples 8 to 15 in which the etching was performed with the fluoro-dithiethane and the second etching compound than in Comparative Examples 6 to 12 in which the etching was performed with only the second etching compound and without using the fluoro-dithiethane.

The etching selectivity of the silicon material to the carbon material was higher in Example 15 in which the hydrogen gas was used as the second etching compound than in a case where the etching gas containing no hydrogen gas was used. This fact showed that the use of the hydrogen gas as the second etching compound enables an increase in the etching selectivity of the silicon material to the carbon material.

When Reference Example 1 in which sulfur hexafluoride having a high metal concentration was used as the etching gas was compared with Comparative Example 8 in which sulfur hexafluoride having a low metal concentration was used as the etching gas, the etching rates of the silicon material and the carbon material were almost the same. This fact suggests that the etching selectivity improvement effect by reducing the metal concentration is peculiar to a specific etching gas.

### REFERENCE SIGNS LIST

200 etching device
210 chamber
220 upper electrode
221 lower electrode
300 fluoro-dithiethane gas supply section
310 inert gas supply section
320 second etching compound gas supply section
400 member to be etched

1. An etching method comprising:
an etching step of bringing an etching gas containing an etching compound into contact with a member to be etched having an etching object subject to etching by the etching gas and a non-etching object not subject to etching by the etching gas and selectively etching the etching object over the non-etching object, wherein
the etching object has a silicon material and the non-etching object has a carbon material,
the etching compound is fluoro-dithiethane represented by Chemical Formula CₓF_{y}S₂, wherein, in Chemical Formula above, x is 2 or more and 6 or less and y is 4 or more and 12 or less, and
the etching gas contains or does not contain at least one type of metal among sodium, magnesium, aluminum, potassium, calcium, chromium, manganese, iron, cobalt, nickel, copper, and molybdenum, and, when the at least one type of metal is contained, a total concentration of all types of the contained metals is 300 ppb by mass or less.

2. The etching method according to claim 1, wherein the fluoro-dithiethane has at least one type among 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane.

3. The etching method according to claim 1, wherein the silicon material has at least one of a silicon compound and polysilicon, and the silicon compound is a compound having at least one of an oxygen atom and a nitrogen atom, and a silicon atom.

4. The etching method according to claim 1, wherein the carbon material has at least one of a photoresist and amorphous carbon.

5. The etching method according to claim 1, wherein the etching gas contains the fluoro-dithiethane and at least one of a second etching compound and an inert gas.

6. The etching method according to claim 5, wherein the second etching compound is at least one type among nitrogen trifluoride, sulfur hexafluoride, chlorine gas, hydrogen gas, and fluorocarbon having 1 or more and 7 or less carbon atoms.

7. The etching method according to claim 6, wherein the fluorocarbon is at least one type among tetrafluoromethane, difluoromethane, and hexafluorobutadiene.

8. The etching method according to claim 2, wherein the silicon material has at least one of a silicon compound and polysilicon, and the silicon compound is a compound having at least one of an oxygen atom and a nitrogen atom, and a silicon atom.

9. The etching method according to claim 2, wherein the carbon material has at least one of a photoresist and amorphous carbon.

10. The etching method according to claim 2, wherein the etching gas contains the fluoro-dithiethane and at least one of a second etching compound and an inert gas.

11. The etching method according to claim 10, wherein the second etching compound is at least one type among nitrogen trifluoride, sulfur hexafluoride, chlorine gas, hydrogen gas, and fluorocarbon having 1 or more and 7 or less carbon atoms.

12. The etching method according to claim 11, wherein the fluorocarbon is at least one type among tetrafluoromethane, difluoromethane, and hexafluorobutadiene.
